(19) United States
(12) Patent Application Publication
(10) Pub. No.: US 2008/0076058 A1
(43) Pub. Date: Mar. 27, 2008

(54) Luminescent photoresist

(76) Inventors: Michael J. Leeson, Portland, OR (US); Heidi B. Cao, Portland, OR (US); Wang Yueh, Portland, OR (US); Jeanette M. Roberts, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/502,916

(22) Filed: Aug. 11, 2006

(51) Int. Cl. G03F 7/004

(52) U.S. Cl. 430/270.1

(57) ABSTRACT

A photoresist composition (phosphoresist) including a resist capable of activation when exposed to electromagnetic energy within a first bandwidth, but relatively insensitive to electromagnetic energy within a second bandwidth and a third bandwidth, and also including a phosphor material included in the photoresist and capable of activation when exposed to electromagnetic energy within the second bandwidth. Photo-luminescent centers included in the phosphoresist are associated with the phosphor material and are capable of emitting luminescence within the first bandwidth in response to exposure to electromagnetic energy within the third bandwidth. The phosphoresist may be disposed as a relatively thin and uniform layer at a surface of a substrate, such as a semiconductor substrate.

### FIELD OF THE INVENTION

The invention relates generally to the field of semiconductor device manufacturing. In particular, the invention relates to photoresist materials for lithographic processing.

### BACKGROUND OF THE INVENTION

Semiconductor lithographic processes include the use of light energy and photosensitive resist materials (photoresist) to transfer patterns from photomasks onto or into materials at the surface of semiconductor substrates. Current photoresist materials used in semiconductor lithography are typically formulated for exposure at a specific wavelength of patterning light, and change in response to the patterning wavelength by becoming soluble in a developer (for so-called positive tone photoresists), or insoluble in a developer (in so-called negative tone photoresists). In other words, the exposed areas become chemically distinguished from the unexposed layers by exposure to the patterning wavelength.

Historically, visible and even near ultraviolet wavelengths delivered at relatively high doses exposed the full thickness of a photoresist layer. However, as feature sizes have shrunken, shorter wavelengths of light have been employed to improve resolution in resist patterns. Extreme ultraviolet light (EUV) considered for future high volume manufacturing of semiconductor devices, however, can currently only be delivered at low doses, insufficient to fully expose and convert currently available photo-sensitive resists for developing. Consequently, forming high resolution features and conforming to line edge roughness targets using EUV wavelength exposure energies is hindered.

One approach taken to improve the sensitivity of current photoresist and facilitate the use of low exposure dose wavelengths involves ‘chemically amplified resists’ (CARs). CARs include a polymer and a photo-acid-generator (PAG). Exposure energies cause the PAG to create an acid in the polymer material, which then converts the polymer to a developer-soluble form when subsequently exposed to thermal energy. One drawback of CARs, however, is that the acid diffuses from the exposed area to unexposed areas, converting the polymer beyond the intended pattern edges. This excessive diffusion negatively affects pattern fidelity, increases line edge roughness and decreases line width control. Therefore, neither chemically amplified resists nor conventional photo-sensitive resists provide adequate feature delineation at the small feature sizes and lower line width roughness requirements of future semiconductor device technologies.

### BRIEF DESCRIPTION OF THE DRAWINGS

FIG. 1 depicts a process involving activation of luminescent centers in a positive tone phosphoresist system according to an embodiment of the invention.

FIG. 2a depicts a cross-sectional view of portions of a phosphoresist material being exposed by short-wavelength electromagnetic energy through open patterns of an opaque mask layer according to an embodiment of the invention.

FIG. 2b depicts a cross-sectional view of portions of a phosphoresist material including activated phosphor material according to an embodiment of the invention.

FIG. 2c depicts a cross-sectional view of a phosphoresist material being exposed by a longer wavelength electromagnetic energy according to embodiments of the invention.

FIG. 2d depicts a cross-sectional view of a cured phosphoresist material according to embodiments of the invention.

FIG. 2e depicts a cross-sectional view of a phosphoresist material including portions where exposed phosphoresist has been removed by a developer according to embodiments of the invention.

### DETAILED DESCRIPTION OF THE INVENTION

For descriptive purposes within this specification, a phosphoresist is a resist material which includes a photostimulated phosphor material. A phosphoresist may be patterned in three operations. The first operation involves a patterning exposure of those areas intended to be patterned, using a low dosage energy at a relatively short wavelength exposure bandwidth. The second operation includes a flood exposure of the resist using a bandwidth of higher dosage, longer wavelength energy than that used for the patterning exposure. The last operation includes developing (clearing) those areas of the phosphoresist exposed by the patterning exposure (in the case of a positive tone system, or alternatively, in a negative tone system, clearing the non-patterned phosphoresist and leaving in place the patterned phosphoresist).

The patterning exposure of the first operation activates a phosphor material in the resist, such that it becomes reactive to electromagnetic energy in the longer wavelength bandwidth of the high dosage flood exposure. The nature of the reactivity is that, when exposed to the longer wavelength energy, luminescent centers of the phosphor material emit electromagnetic energy in a third bandwidth, generally at a different wavelength than either the patterning bandwidth or the flood exposure bandwidth. Electrons of the luminescent centers continually cycle between an excited state and a lower energy state for as long as the flood exposure continues, emitting luminescent energy with each return to the lower energy state.

The resist material, which generally is only marginally soluble (or even insoluble) to a developer in a positive tone system, and is relatively insensitive (transparent) to energy in the patterning and flood exposure wavelengths, is converted to a more developer-soluble state in a photochemical reaction driven by one or more wavelengths in the bandwidth of energy emitted by the luminescent centers. In addition to becoming more soluble, the converted resist material also bleaches, becoming more transparent to the emitted wavelength of energy from the luminescent centers and allowing that energy to penetrate farther through the resist. Thus, the longer the flood exposure continues, the farther the zone of converted resist extends away from each luminescent center. Although a phosphoresist is described relating to a positive tone system herein, the embodiments are not so limited. For example, a phosphoresist can also be used in a negative tone system according to alternative embodiments, wherein the luminescent energy drives a reaction that converts the patterned resist into a form that is more resistant to dissolution in a developer.

As described according to embodiments of the invention, patterns are defined in a resist material using a high resolution, low dose patterning energy, and development of the defined patterns may be tuned based on the density of a phosphor material included within the resist, and by varying the duration of the relatively high dose, longer wavelength flood exposure. By the materials and operations described herein, small, finely resolved features can be lithographically produced using existing lithographic equipment and materials, largely obviating the need for increased capital expenditure to develop new equipment and replace existing manufacturing lines.

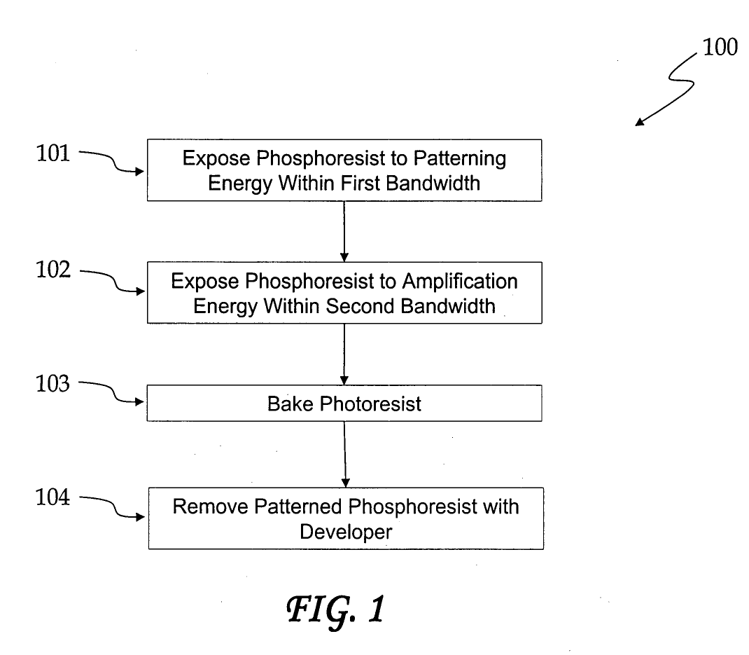

With reference to FIG. 1, an embodiment of a method 100 includes exposing a phosphoresist material to electromagnetic energy within a first bandwidth comprised of relatively short wavelengths, hereinafter referred to as a ‘patterning’ exposure, bandwidth, or energy. Among examples of patterning bandwidths are those including vacuum ultraviolet (VUV), extreme ultraviolet (EUV) and X-ray, although the embodiments are not so limited. Vacuum UV wavelengths are generally found in the range of approximately 10-200 nanometers (nm), extreme ultraviolet wavelengths are generally found in the range of approximately 1-31 nm, and X-ray wavelengths are generally found in the range of approximately 10-0.01 nm. Patterning bandwidths may include energy peaking at a single wavelength (e.g., 200 nm.), energy peaking at multiple wavelengths, or multiple wavelengths within a single broad peak.

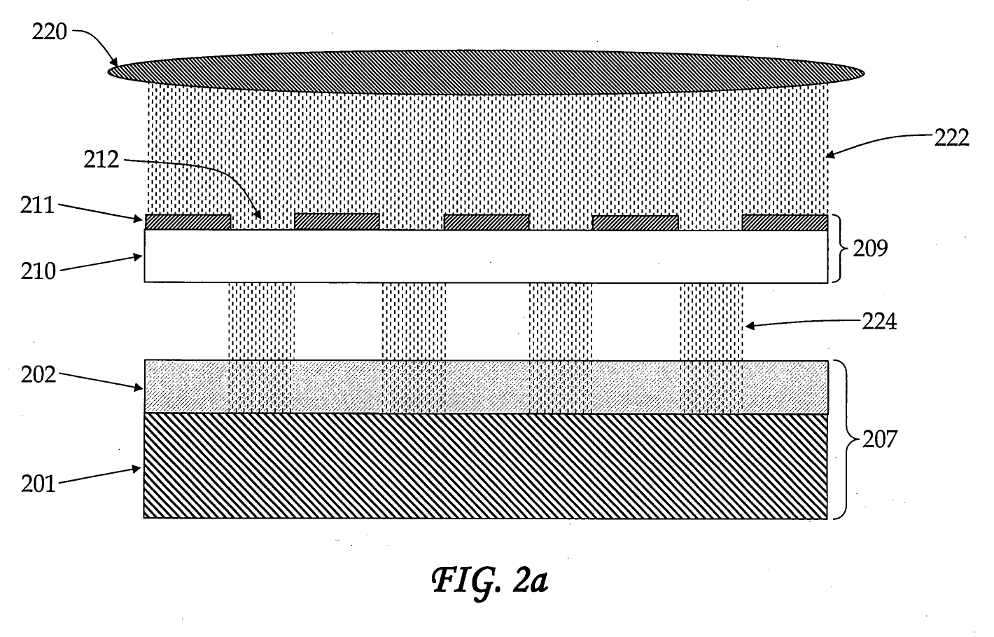

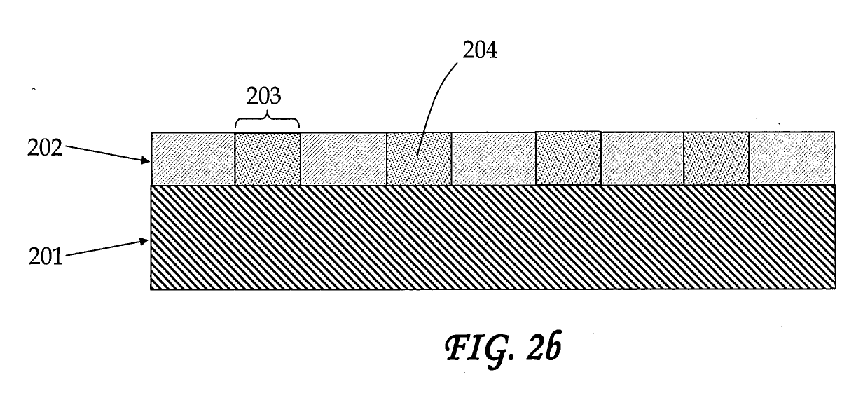

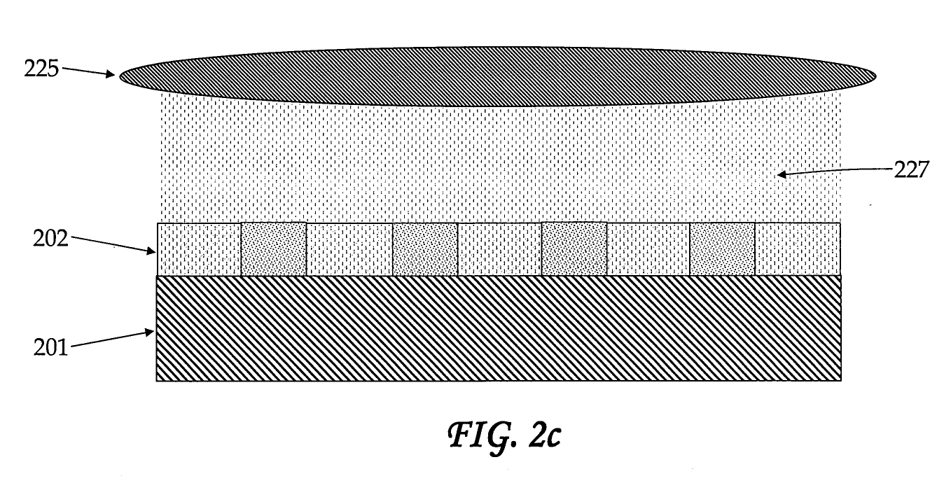

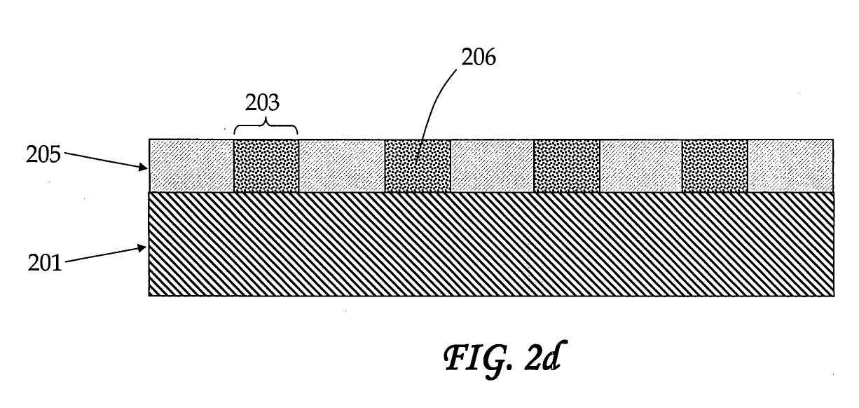

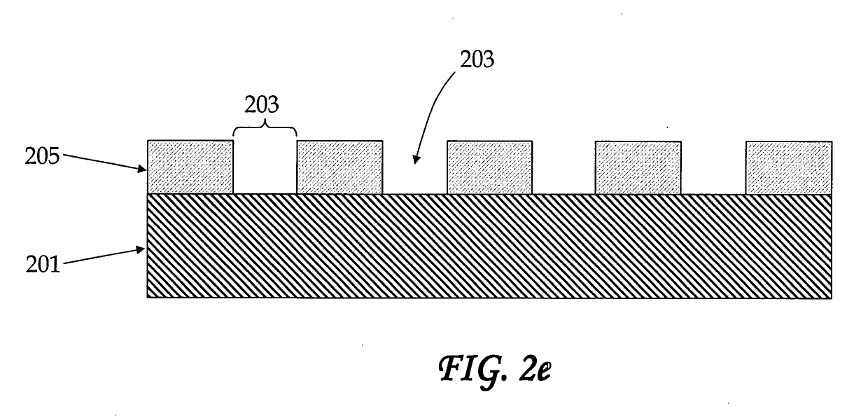

With reference to an embodiment depicted in FIG. 2a, a phosphoresist composition 202 is disposed, generally as a relatively thin layer, at a surface of a substrate 201, forming an assembly 207. The thickness of a disposed photoresist layer is typically relatively uniform, and substantially covers the substrate surface, although some portions of the surface may remain uncovered, either intentionally or incidentally. A substrate 201 may include a semiconductor material such as silicon, germanium, or gallium, although the embodiments are not so limited. For example, a substrate 201 could be the substrate of a printed circuit board (or card, or flexible printed circuit substrate) upon which very small features are to be formed. In the broadest sense, the substrate 201 could be nearly any substrate that may be patterned using photolithographic processing. A mask 209 comprising a transparent layer 210 and an opaque layer 211 is positioned between an energy source 220 and the phosphoresist 202, with openings 212 provided in the opaque layer 211 corresponding to areas of the phosphoresist 202 to be patterned. An energy source 220 emits a patterning energy 222, directed at least in part toward the phosphoresist, wherein the energy is blocked by areas of the mask 209 still having the opaque layer 211, but penetrates through the transparent layer 210 of the mask 209 in areas corresponding to openings 212 where the opaque layer 211 is absent. The penetrating energy 224 acts as a patterning exposure to activate a phosphor material in the phosphoresist.

Other forms of pattern transfer, such as a reflective mask, are also used in alternative embodiments of the invention. Regarding a reflective mask, rather than patterning energy penetrating through transparent portions of a mask and exposing the phosphoresist, the patterning energy is reflected off reflective patterns of a mask to expose the resist. Energy striking portions of the mask which do not contain reflective patterns, correspondingly, do not reflect patterning energy onto the resist.

According to alternate embodiments, the patterning energy comprises a narrow beam of energy rather than a flood exposure, capable of high resolution exposure of very small areas of phosphoresist in a scanning or ‘step and repeat’ spot exposure, and a mask 209 is not used. However, it is also possible to use a mask in such alternate embodiments, as it may aid the high resolution patterning of some features in a phosphoresist.

As discussed, the phosphoresist 202 includes a phosphor material that is sensitive to activation energies in the short wavelengths, including energies in any one of the VUV, EUV, and X-ray bandwidths. One example of a photostimulated phosphor material is BaFBr, with trace amounts of Eu²⁺ luminescent centers, which absorbs energy in the short wavelengths of the patterning energy. Exposure to a patterning energy induces ‘excited’ valence electrons to move toward the halogen ions from the Eu²⁺ ions, forming localized, metastable color centers. Excitation of the Eu²⁺ luminescent centers has been shown to take place with activation energies as low as 6.9 eV, which can be provided by a low dosage, short wavelength exposure that would otherwise be insufficient to expose the full thickness of a conventional PAC (photoactive compound) or PAG (photo-acid generator) containing resist. Therefore, exposing luminescent centers to patterning energies exceeding an excitation energy threshold (e.g., 6.9 eV) will activate the luminescent centers of the phosphor material. The more Eu²⁺ ions are present in the phosphoresist, the more luminescent centers may be formed by the patterning exposure, potentially improving the resolution of subsequently developed patterns in the resist. Further, luminescent centers remain in an activated state for up to several days, providing a sufficient time window to accomplish subsequent exposure operations in a high volume manufacturing environment.

With reference to FIG. 2b, patterns 203 corresponding in location and dimensions to where a patterning energy 224 strikes the surface of a phosphoresist material 202, are formed extending from the surface of the phosphoresist 202 to the surface of the substrate 201. The patterns comprise phosphoresist material containing activated luminescent centers 204, as differentiated from the surrounding phosphoresist material 202 which contains unexposed and unactivated luminescent centers. The resist material itself, being relatively transparent to and unaffected by energies within the patterning bandwidth, remains relatively unchanged throughout. Some small amount of photochemistry may take place in the resist due to secondary electrons generated by the patterning energy, but generally the dosage of the short wavelength patterning energy is too low to alter the solubility of the phosphoresist. Therefore, pattern development is not caused by the patterning energy other than through the action of the luminescent centers 204, as further described below.

Referring again to FIG. 1 at 102, after exposure of the phosphoresist to the patterning energy, the phosphoresist is then exposed to energy within a second bandwidth, referred to hereinafter as an amplification exposure, or amplification energy. The amplification energy 227, as shown in the embodiment depicted in FIG. 2c, is generally delivered from an energy source 225 in a flood exposure across the surface of the phosphoresist 202, and is generally of a much longer wavelength than that of the patterning energy. Therefore, regions of the phosphoresist containing both activated luminescent centers 204 and non-activated luminescent centers are exposed to the amplification energy 227. An example of an activation energy bandwidth includes energy at a wavelength of 600 nm (nanometers), at which the luminescent centers are sensitive, but the resist material is relatively insensitive, or transparent, including any polymers, PAG, or PAC included in the resist. Another characteristic of the amplification energy is a high energy dosage, which easily penetrates through the resist to the surface of the substrate 201. The substrate surface may also include an anti-reflective surface coating or treatment to reduce reflection of amplification energy 227 striking the substrate surface.

In response to exposure to the amplification energy 227, electrons in the luminescent centers cycle between an excited state and a lower energy state, emitting luminescence with each return to the lower energy state. Cycling between states continues as long as exposure to the amplification energy continues, providing a method to control the extent of exposure of the resist material to the emitted luminescent energy by controlling the duration of exposure to the amplification energy. The emitted luminescence, or luminescent energy, generally comprises energy at a third bandwidth, which includes a different wavelength of energy from either the patterning energy or the amplification energy. In one example, the bandwidth of the emitted luminescence includes energy at the 400 nm wavelength.

As the amplification energy penetrates throughout the thickness of the resist material, substantially all of the activated luminescent centers throughout the resist thickness emit luminescence simultaneously. At least a portion of the bandwidth of the luminescent energy includes energy at an operative wavelength, that is, a wavelength or bandwidth of wavelengths capable of initiating conversion of the resist, as discussed below. The luminescent energy travels outward through the resist from the luminescent centers until it is absorbed by a molecule of a PAC in the resist material (when the resist is a non-chemically amplified resist) (e.g., novolac) or a PAG molecule in the resist material (when the resist is a chemically amplified resist). The resist material generally also includes a polymer which may be transparent to the luminescent energy, so the polymer does not substantially impede the transmission of the luminescent energy through the resist material. PAC molecules normally act as a dissolution inhibitor for a resist polymer material. However, upon absorbing the luminescent energy, the PAC molecules undergo a photochemical process which alters the solubility of the resist material (referred to hereinafter as ‘conversion’ of the resist), rendering it more soluble to a conventional developer solution (when part of a positive tone system, or, rendering the patterned resist less soluble to a developer solution when part of a negative tone system). Luminescence from a single luminescent center can affect numerous PAC molecules in numerous directions substantially simultaneously. Therefore, conversion takes place in multiple directions outward from each luminescent center throughout the duration of exposure to amplification energy.

With reference to FIG. 2d, only activated luminescent centers within the patterns 203 defined by the patterning exposure, emit luminescent energy in response to exposure to amplification energy. Therefore, initially, only resist material 206 in the immediate area of the activated luminescent centers undergoes conversion (solubility change) by the PAC-induced photochemical reaction. However, as the PAC photochemical reaction takes place, the affected PAC molecules tend to ‘bleach’, becoming transparent to the emitted luminescent energy, which is then free to travel farther through the resist material, affecting other, more distantly located PAC molecules. Thus, as long as the luminescent centers are exposed to amplification energy, and continue to emit luminescence, the area of converted resist material continues to expand. It is possible for resist material 205 beyond the boundary of the patterns 203 defined by the patterning exposure to also be converted, so one or more of several ‘regulating’ measures may be taken to control the expansion of the converted zone of resist material.

A primary regulating measure is simply to terminate exposure of the luminescent centers to the amplification energy. By removing the amplification energy, the luminescent centers will cease to cycle between the excited and lower energy states, and ceasing to emit luminescence. Without the luminescent energy in the operative wavelength (e.g., 400 nm), additional PAC molecules are not activated, and already existing PAC-based photochemical reactions quickly exhaust themselves, ending conversion of resist. Thus, although terminating exposure to amplification energy may not immediately terminate resist conversion, it removes the driving mechanism for the electronic cycling of the luminescent centers, and the subsequent chain of events leading to resist conversion is not sustained.

Conversion can also be slowed by including a dye that absorbs energy in the operative wavelength, for example, 400 nm, in the resist material. While the bleaching of PAC molecules allows luminescent energy to pass through the resist relatively unimpeded, inclusion of a dye in the resist provides an impediment to luminescent energy transmission. Depending on the amount of such dye included in the resist, the distance that emitted luminescence can travel beyond the luminescent centers and through the resist may be limited to varying degrees. Therefore, the amount of dye can be adjusted to regulate the range of transmission, as well as to tune the absorbance of the resist to a specific wavelength or bandwidth of energy. Likewise, although perhaps less preferred, the structure of a polymer or PAG in the resist can be modified to adjust or tune the overall energy absorbance of the resist. These methods are useful for regulating expansion of the range of PAC activation and resist conversion.

Alternatively, the density of luminescent centers provided in the resist can be kept fairly low. While this helps to regulate the rate and range of resist conversion, it can negatively impact the resolution of patterns, and necessitate longer amplification exposure to assure sufficient clearing (development) of resist in the patterned areas. For example, luminescent centers generally emit luminescent energy outward in all directions, in a roughly spherical pattern outward from the centers. As the luminescent energy causes PAC photochemical reactions, the subsequent bleaching of PAC molecules progresses outward from each luminescent center, increasing the size of each ‘sphere’ of luminescent energy transmission. Therefore, the ‘surface’ of each sphere defines an expanding curve through the resist material as long as amplification energy continues to be provided. When the density of luminescent centers in a resist material is low, each sphere of luminescent energy transmission generally will expand until it intersects with the similarly expanding transmission spheres of adjacent luminescent centers. Eventually, substantially all of the resist material between the luminescent centers and within the boundaries of the exposure pattern 203 is converted. However, in that situation, the convergence of the curved surfaces of numerous expanded transmission spheres at the outer limit of an area of converted resist will form a boundary defined by relatively large curves, rather than a boundary defined by, or defining, a smooth and straight line. When the converted resist is developed away, the resulting patterns will exhibit substantial line edge roughness.

In an alternate situation, however, the density of luminescent centers provided in a phosphoresist material is relatively high. In this alternate situation, the outwardly expanding spheres of transmitted luminescent energy from each luminescent center will intersect those of adjacent centers while the spheres are still relatively small, and a relatively short duration amplification exposure is sufficient to convert substantially all of the resist within the patterned areas. As a result, the boundary or line edge of a pattern is defined by a large number of relatively small curves, rather than a small number of relatively large curves, and will yield a smoother line edge in the developed patterns. Therefore, a relatively higher density of luminescent centers in a phosphoresist can provide better image resolution and improved line edge roughness.

Other embodiments of a phosphoresist include a PAG, or photo-acid-generator, rather than a PAC as described above. When using a PAG-containing phosphoresist, the emitted luminescence energy from the luminescent centers causes the PAG to release acid into the resist in the exposed areas. Referring to FIG. 1, after exposing the phosphoresist to amplification energy, the phosphoresist can be baked, as at 103. Exposure to thermal energy during baking causes the PAG-generated acid to convert the resist into a developer soluble form. Conversion can be controlled in part by controlling the duration of exposure to amplification energy, therefore controlling the amount of acid formed in the resist, by controlling the duration of the bake operation, therefore controlling the rate and amount of resist converted by the acid, or by controlling both. Longer amplification exposure and/or longer bake operations can each result in a greater amount of phosphoresist conversion, and if excessive, can cause blurring of feature edges or other detrimental results in the developed resist.

With reference to FIG. 1 at 104, the converted resist is removed by exposing it to a developer, such as an organic solvent or aqueous developer solution (when used in a positive tone system, or, the converted resist remains and the unconverted resist is removed when used in a negative tone system). As depicted in FIG. 2e, for example, in the patterned areas 203, substantially all of the converted resist is removed, leaving an opening in the resist layer to the surface of the substrate 201. Such openings correspond with the patterns 203 originally exposed to the patterning energy, and with the portions of resist in which the luminescent centers were activated. The unconverted resist 205, however, remains relatively insoluble in the developer, and is not removed from the surface of the substrate 201, or may be only minimally removed.

As described, a phosphoresist can include a polymer, which is generally substantially transparent to energy in the patterning, amplification, and luminescent energy wavelengths. It may also include either a PAG or a PAC which is substantially transparent at the patterning and amplification wavelengths, but absorbs energy in a wavelength of the luminescent energy. A phosphoresist also includes a phosphor material, such as BaFBr:Eu²⁺, from which the Eu²⁺ are activated at the patterning wavelength, and which emit energy at a luminescent wavelength when exposed to energy at an amplification wavelength. A phosphoresist may also, in embodiments, include a dye that is relatively opaque to energy at a luminescent wavelength, in an amount tuned to prevent excessive conversion of resist material beyond the patterned areas. A phosphoresist may include other materials in alternate embodiments, as may be useful for preparing, coating/applying, curing, or developing the resist material. Further, a phosporesist according to embodiments of this invention can be formulated for an aqueous developer, an organic solvent developer, or another form of developer, without departing from the spirit of the embodiments described herein. Nor are the embodiments limited by the exact source of the patterning or amplification energies, nor by the method by which those energies are caused to encounter the resist.

The foregoing detailed description and accompanying drawings are only illustrative and not restrictive. They have been provided primarily for a clear and comprehensive understanding of the embodiments of the invention, and no unnecessary limitations are to be understood therefrom. Numerous additions, deletions, and modifications to the embodiments described herein, as well as alternative arrangements, may be devised by those skilled in the art without departing from the spirit of the embodiments and the scope of the appended claims.

We claim:

1. A photoresist composition, comprising:
a resist capable of activation when exposed to electromagnetic energy within a first bandwidth, but relatively insensitive to electromagnetic energy within a second bandwidth and a third bandwidth;
a phosphor material included in the photoresist and capable of activation when exposed to electromagnetic energy within the second bandwidth; and
photo-luminescent centers associated with the phosphor material and capable of emitting luminescence within the first bandwidth in response to exposure to electromagnetic energy within the third bandwidth.

2. The photoresist composition of claim 1, wherein the second electromagnetic bandwidth comprises a wavelength selected from at least one of a group consisting of vacuum ultraviolet (VUV), extreme ultraviolet (EUV) and X-ray wavelengths.

3. The photoresist composition of claim 1, further comprising a dye capable of absorbing energy within the first electromagnetic bandwidth.

4. The photoresist composition of claim 1, wherein the phosphor material comprises BaFBr.

5. The photoresist composition of claim 1, wherein the luminescent centers comprise Eu²⁺.

6. The photoresist composition of claim 1, wherein the resist comprises at least one of a chemically amplified photoresist or a non-chemically amplified photoresist.

7. The photoresist composition of claim 1, wherein activation of the resist comprises increasing the solubility in a developer of the portions of the resist exposed to energy of the first bandwidth.

8. The photoresist composition of claim 1, wherein activation of the resist comprises decreasing the solubility in a developer of the portions of the resist exposed to energy of the first bandwidth.

9. The photoresist composition of claim 1, wherein activation of the resist comprises generating an acid in the exposed portions of the resist which, when exposed to thermal energy, increases the solubility of the resist in a developer.

10. The photoresist composition of claim 1, wherein activation of the phosphor material comprises exposing the luminescent centers to energy of the operative wavelength and in excess of an excitation energy threshold.

11. The photoresist composition of claim 1, disposed as a relatively thin layer adjacent to a surface of a substrate.

12. The photoresist composition of claim 1, wherein the third bandwidth of energy includes energy at a wavelength of approximately 600 nanometers.

13. The photoresist composition of claim 1, wherein the first bandwidth of energy includes energy at a wavelength of approximately 400 nanometers.

14. A method, comprising:
exposing portions of a disposed phosphoresist material to electromagnetic energy within a first bandwidth and activating a phosphor material in the portions of the phosphoresist, the portions corresponding with a predetermined pattern; and
exposing the phosphoresist to electromagnetic energy within a second bandwidth, the energy within the second bandwidth causing luminescent centers to emit electromagnetic energy within a third bandwidth in the portions of the resist corresponding to the pattern, and the energy within the third bandwidth converting the phosphoresist.

15. The method of claim 14, wherein converting the phosphoresist comprises increasing the solubility of the exposed portions of the photoresist in a developer.

16. The method of claim 14, wherein converting the phosphoresist comprises decreasing the solubility of the exposed portions of the photoresist in a developer.

17. The method of claim 14, wherein the phosphoresist material is disposed as a relatively thin layer adjacent to a surface of a substrate.

18. The method of claim 14, wherein converting the phosphoresist comprises activating an acid generator, and further comprising exposing the phosphoresist material to electromagnetic energy of a fourth bandwidth, wherein the energy in the fourth bandwidth cause a photochemical reaction altering the solubility of the phosphoresist.

19. The method of claim 14, further comprising exposing the phosphoresist material to a developer and substantially removing the converted phosphoresist.

20. The method of claim 14, further comprising including a dye within the phosphoresist material wherein the dye is capable of absorbing electromagnetic energy within the third bandwidth.

21. The method of claim 14, wherein the phosphoresist material is relatively insensitive to electromagnetic energy within the first and second bandwidths.

22. The method of claim 14, wherein the predetermined pattern is formed of openings in a mask layer of an optical substrate, and wherein the optical substrate is relatively transparent to electromagnetic energy within a first bandwidth, and the mask layer is opaque to electromagnetic energy within the first bandwidth.

23. An assembly, comprising:
a semiconductor substrate; and
a photoresist composition disposed at a surface of the substrate, the photoresist composition material comprising:
a polymer capable of activation when exposed to electromagnetic energy within a first bandwidth, but relatively insensitive to electromagnetic energy within a second bandwidth and a third bandwidth;
a phosphor material included in the photoresist and capable of activation when exposed to electromagnetic energy within the second bandwidth; and
photo-luminescent centers associated with the phosphor material and capable of emitting luminescence within the first bandwidth in response to exposure to electromagnetic energy within the third bandwidth.

24. The assembly of claim 22, wherein the photoresist composition comprises a relatively thin layer of relatively uniform thickness and substantially covers the surface of the substrate.

25. The assembly of claim 22, wherein the substrate comprises a material selected from the group consisting of silicon, gallium, and germanium.
